(19) United States
(12) Patent Application Publication
(10) Pub. No.: US 2024/0337940 A1
(43) Pub. Date: Oct. 10, 2024

(54) SOLVENT SYSTEMS FOR SELECTIVE REMOVAL OF POLYMERIC MATERIALS

(71) Applicant: ENTEGRIS, INC., Billerica, MA (US)

(72) Inventors: Hsing-Chen Wu, Hsinchu City (TW); Eri Hirahara, Shizuoka-shi (JP); Ming-Chi Liao, Taoyuan City (TW); Min-Chieh Yang, Hsinchu City (TW)

(21) Appl. No.: 18/624,231

(22) Filed: Apr. 2, 2024

Related U.S. Application Data
(60) Provisional application No. 63/457,360, filed on Apr. 5, 2023.

(51) Int. Cl. G03F 7/039; C08F 297/02; G03F 7/00; G03F 7/32

(52) U.S. Cl. CPC G03F 7/0397; C08F 297/026; G03F 7/32; G03F 7/70033

(57) ABSTRACT

Solutions for selective removal of polymer chains from layers of block copolymers and related methods are provided. A layer of a block copolymer comprises a plurality of polymer domains, each of the polymer domains comprise a first region and a second region. The first region comprises first polymer chains. The second region comprises second polymer chains. The solution is configured to remove a greater proportion of the second polymer chains than the first polymer chains, sufficient to increase or rectify at least one dimension of the plurality of polymer domains.

### FIELD

The present disclosure relates to solvent systems for selective removal of polymeric materials and related methods.

### BACKGROUND

Conventional methods for patterning microchips do not effectively remove polymeric materials. This inability to remove the polymeric layers prevents further advancement and patterning scaling.

### SUMMARY

Some embodiments relate to a method comprising: obtaining a layer of a polystyrene-b-polymethyl methacrylate block copolymer, wherein the layer comprises a plurality of polymer domains, each of the plurality of polymer domains comprising: a first region comprising polystyrene chains; a second region comprising polymethyl methacrylate chains; contacting the layer with a solution to remove at least a portion of the polymethyl methacrylate chains from the second region, so as to form a porous layer or a layer having a surface morphology, wherein the solution removes a greater proportion of the polymethyl methacrylate chains than the polystyrene chains.

Some embodiments relate to a method comprising: obtaining a layer of a polystyrene-b-polymethyl methacrylate block copolymer, wherein the layer comprises a plurality of polymer domains, each of the plurality of polymer domains comprising: a first region comprising polystyrene chains; a second region comprising polymethyl methacrylate chains; exposing the layer to ultraviolet light, wherein the ultraviolet light cleaves at least a portion of the polymethyl methacrylate chains present in the second region; contacting the layer with a solution to remove at least a portion of the polymethyl methacrylate chains from the second region, so as to form a porous layer or a layer having a surface morphology, wherein the solution removes a greater proportion of the polymethyl methacrylate chains than the polystyrene chains.

Some embodiments relate to a method comprising: obtaining a layer of a polystyrene-b-polymethyl methacrylate block copolymer, wherein the layer comprises a plurality of polymer domains, each of the plurality of polymer domains comprising: a first region comprising polystyrene chains; a second region comprising polymethyl methacrylate chains; a third region between the first region and the second region, wherein the third region comprises an unsegregated portion of polystyrene chains and polymethyl methacrylate chains; contacting the layer with a solution to remove at least a portion of the polymethyl methacrylate chains from the second region and the third region, so as to form a porous layer or a layer having a surface morphology, wherein the solution removes a greater proportion of the polymethyl methacrylate chains than the polystyrene chains.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a schematic diagram of a domain of a phase-segregated block copolymer, according to some embodiments.

FIG. 2 is a flowchart of a method for selective removal of polymer chains, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

Some embodiments relate to solvent systems for selective removal of polymeric materials and related methods. In some embodiments, solvent systems for rectifying a critical dimension of patterned layers useful in semiconductor fabrication, including microchip fabrication, are provided. The solvent systems can be combined with directed phase segregation of block copolymers technology to increase the critical dimension of patterned layers. Through directed phase segregation of block copolymers, a layer of a polystyrene-b-polymethyl methacrylate block copolymer can be formed by coating and annealing on guiding pattern layers, so as to obtain a structural pattern. The solvent systems disclosed herein may be employed for selective removal of the polymethyl methacrylate chains in the various regions of each polymer domain of the phase-segregated block copolymer layer.

Unlike conventional solvent systems, the solvent systems disclosed herein can be employed for selective removal of polymethyl methacrylate chains over polystyrene chains. The selective removal of polymethyl methacrylate chains can include polymethyl methacrylate chains present in a region comprising only polymethyl methacrylate chains, as well as regions comprising both polymethyl methacrylate chains and polystyrene chains. The solvent systems disclosed herein can also be employed to increase or rectify a critical dimension of the layer (e.g., hole diameter of each polymer domain) or pattern relative to, for example, a conventional approach. The solvent systems disclosed herein can be employed to improve pattern uniformity after wet chemical development. The solvent systems disclosed herein can be employed to remove impurities. These and other benefits will become apparent to those skilled in the art in view of the disclosure herein.

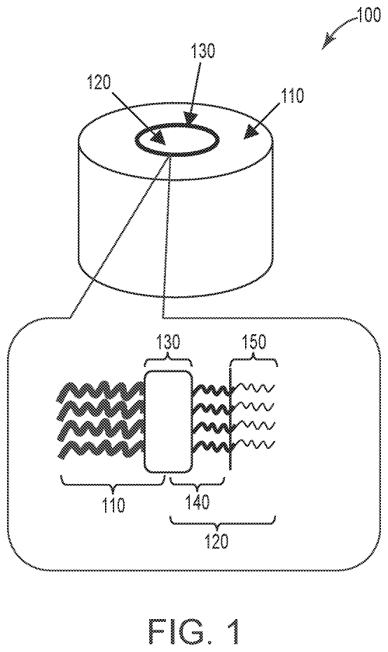

FIG. 1 is a schematic diagram of a domain 100 of a layer of a phase-segregated block copolymer, according to some embodiments. As shown in FIG. 1, in some embodiments, the domain 100 comprises at least one of a first region 110, a second region 120, a third region 130, or any combination thereof. In some embodiments, the first region 110 comprises, consists of, or consists essentially of polystyrene chains. In some embodiments, the second region 120 comprises, consists of, or consists essentially of polymethyl methacrylate chains. In some embodiments, the third region is between the first region 110 and the second region 120. In some embodiments, the third region 130 comprises an intermixed region. In some embodiments, the third region 130 comprises, consists of, or consists essentially of an unsegregated portion of polystyrene chains and polymethyl methacrylate chains. In some embodiments, the second region does not comprise polystyrene chains. In some embodiments, the first region does not comprise polymethyl methacrylate chains.

As used herein, the term “cleave” refers to any form of damage or degradation to a bond. In some embodiments, the term “cleave” refers to a broken chemical bond. In some embodiments, a polymer chain that is cleaved results in broken chemical bond such that the polymer chain has a cleaved portion of the polymer chain and a non-cleaved portion of the polymer chain. In some embodiments, the polymethyl methacrylate chains present in the second region 120 have not been cleaved. In some embodiments, the polymethyl methacrylate chains present in the second region 120 have been at least partially cleaved. In some embodiments, the polymethyl methacrylate chains present in the second region 120 have been cleaved. In some embodiments, the polymethyl methacrylate chains present in the second region 120 comprise non-cleaved polymethyl methacrylate chains 140 and cleaved polymethyl methacrylate chains 150.

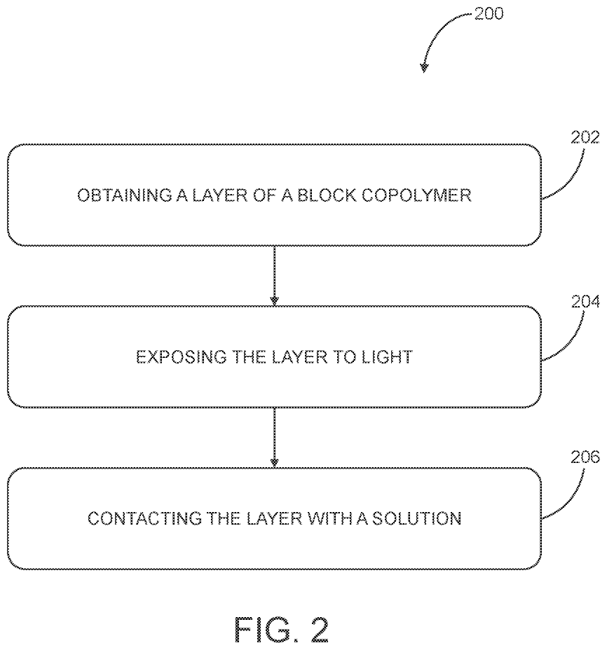

FIG. 2 is a flowchart of a method 200 for selective removal of polymer chains, according to some embodiments. As shown in FIG. 2, in some embodiments, the method 200 comprises one or more of the following steps: obtaining 202 a layer of a block copolymer; exposing 204 the layer to ultraviolet light; and contacting 206 the layer with a solution, so as to form a porous layer or a layer having a surface morphology.

At step 202, in some embodiments, a layer of a block copolymer is obtained. In some embodiments, the layer of the block copolymer comprises a layer of a phase segregated block copolymer. In some embodiments, the layer of the block copolymer comprises a layer of a polystyrene-b-polymethyl methacrylate block copolymer. In some embodiments, the layer of the polystyrene-b-polymethyl methacrylate block copolymer comprises a plurality of polymer domains. In some embodiments, the plurality of polymer domains is formed as a result of the phase segregation of the polystyrene-b-polymethyl methacrylate block copolymer. In some embodiments, the plurality of polymer domains is formed as a result of the guided phase segregation of the polystyrene-b-polymethyl methacrylate block copolymer.

Each of the plurality of polymer domains may comprise, consist of, or consist essentially of at least one of a first region, a second region, a third region, or any combination hereof. In some embodiments, the first region comprises, consists of, or consists essentially of polystyrene chains. In some embodiments, the second region comprises, consists of, or consists essentially of polymethyl methacrylate chains. In some embodiments, the third region is a region located between the first region and the second region. In some embodiments, the third region comprises an intermixed region. In some embodiments, the third region comprises a region in which the polystyrene chains and the polymethyl methacrylate chains are not fully segregated. In some embodiments, the third region comprises, consists of, or consists essentially of an unsegregated portion of polystyrene chains and polymethyl methacrylate chains.

The layer of the polystyrene-b-polymethyl methacrylate block copolymer may comprise at least one impurity. In some embodiments, the impurity is present in the first region. In some embodiments, the impurity is present in the second region. In some embodiments, the impurity is present in the third region. In some embodiments, the impurity comprises a styrenic impurity. In some embodiments, the impurity comprises a methyl methacrylate impurity. In some embodiments, the impurity comprises at least one of the following: at least one additive, at least one byproduct, at least one residue (e.g., from the third region or intermixing region), or any combination thereof.

At step 204, in some embodiments, the layer is exposed to ultraviolet light. In some embodiments, the ultraviolet light comprises light having a wavelength in a range of 10 nm to 400 nm, or any range or subrange therebetween. In some embodiments, the ultraviolet light comprises extreme ultraviolet light (EUV). As used herein, the term “extreme ultraviolet light” refers to light used in extreme ultraviolet light lithography. In some embodiments, the ultraviolet light utilizes photons to expose photoresist. In some embodiments, the ultraviolet light comprises 13.5 nm photons to expose photoresist. In some embodiments, the ultraviolet light comprises light having a wavelength in a range of 10 nm to 375 nm, 10 nm to 350 nm, 10 nm to 325 nm, 10 nm to 300 nm, 10 nm to 275 nm, 10 nm to 250 nm, 10 nm to 225 nm, 10 nm to 200 nm, 10 nm to 175 nm, 10 nm to 150 nm, 10 nm to 125 nm, 10 nm to 100 nm, 10 nm to 75 nm, 10 nm to 50 nm, 10 nm to 25 nm, 25 nm to 400 nm, 50 nm to 400 nm, 75 nm to 400 nm, 100 nm to 400 nm, 125 nm to 400 nm, 150 nm to 400 nm, 175 nm to 400 nm, 200 nm to 400 nm, 225 nm to 400 nm, 250 nm to 400 nm, 275 nm to 400 nm, 300 nm to 400 nm, 325 nm to 400 nm, 350 nm to 400 nm, or 375 nm to 400 nm.

The exposure of the layer to ultraviolet light may be sufficient to damage, degrade, or otherwise break chemical bonds of the polymer chains. The exposing may selectively cleave polymethyl methacrylate chains over polystyrene chains. In some embodiments, the exposing cleaves a greater proportion of the polymethyl methacrylate chains present in the second region than the polystyrene chains present in the first region. In some embodiments, the exposing cleaves a greater proportion of the polymethyl methacrylate chains present in the third region than the polystyrene chains present in the third region. In some embodiments, the exposing cleaves a greater proportion of the polymethyl methacrylate chains present in the third region than the polystyrene chains present in the first region. In some embodiments, the exposing cleaves a greater proportion of the polymethyl methacrylate chains present in the second region than the polystyrene chains present in the third region. In some embodiments, the exposing does not cleave any of the polystyrene chains present in at least one of the first region, the third region, or any combination thereof.

The exposing may cleave at least a portion of the polymethyl methacrylate chains present in at least one of the regions of the plurality of polymer domains. In some embodiments, the exposing cleaves at least a portion of the polymethyl methacrylate chains present in the second region. In some embodiments, as a result of the cleaving, the second region comprises polymethyl methacrylate chains, wherein the polymethyl methacrylate chains comprise a cleaved portion of the polymethyl methacrylate chains and a non-cleaved portion of the polymethyl methacrylate chains. In some embodiments, the exposing cleaves at least a portion of the polymethyl methacrylate chains present in the third region. In some embodiments, as a result of the cleaving, the third region comprises polymethyl methacrylate chains, wherein the polymethyl methacrylate chains comprise a cleaved portion of the polymethyl methacrylate chains and a non-cleaved portion of the polymethyl methacrylate chains.

In some embodiments, cleaving by exposing to ultraviolet light does not remove any polymer chains, so as to increase or rectify at least one dimension (e.g., a critical dimension, such as, for example and without limitation, a pore diameter) of at least one of the plurality of polymer domains.

At step 206, in some embodiments, the layer is contacted with a solution. The solution may be configured to remove at least a portion of the polymethyl methacrylate chains from the layer, so as to increase or rectify at least one dimension (e.g., a critical dimension, such as, for example and without limitation, a pore diameter) of at least one of the plurality of polymer domains. In some embodiments, the term “remove” also means to cleave, as defined herein. In some embodiments, the contacting removes at least a portion of the polymethyl methacrylate chains present in at least one of the regions of the plurality of polymer domains. In some embodiments, the contacting removes at least a portion of the polymethyl methacrylate chains present in the second region. In some embodiments, the contacting removes at least a portion of the non-cleaved polymethyl methacrylate chains present in the second region. In some embodiments, the contacting removes at least a portion of the polymethyl methacrylate chains present in the third region. In some embodiments, the contacting removes at least a portion of the non-cleaved polymethyl methacrylate chains present in the third region.

The solution may selectively remove polymethyl methacrylate chains over polystyrene chains sufficient to increase or rectify at least one dimension (e.g., a critical dimension, such as, for example and without limitation, a pore diameter) of at least one of the plurality of polymer domains. In some embodiments, the contacting removes a greater proportion of the polymethyl methacrylate chains present in the second region than the polystyrene chains present in the first region. In some embodiments, the contacting removes a greater proportion of the polymethyl methacrylate chains present in the second region than the polystyrene chains present in the third region. In some embodiments, the contacting removes a greater proportion of the polymethyl methacrylate chains present in the third region than the polystyrene chains present in the third region. In some embodiments, the contacting removes a greater proportion of the polymethyl methacrylate chains present in the third region than the polystyrene chains present in the first region.

The solution may be formulated or configured to remove a greater portion of the polymethyl methacrylate chains from at least one of the second region, the third region, or any combination thereof, than a conventional solution, such as, a conventional solution comprising or consisting of isopropyl alcohol (IPA). In some embodiments, the solution comprises, consists of, or consists essentially of at least one of the following: at least one organic solvent, at least one aqueous solution, at least one alcohol solvent, at least one pH adjuster, or any combination thereof. In some embodiments, the solution comprises, consists of, or consists essentially of at least one organic solvent. In some embodiments, the solution comprises, consists of, or consists essentially of at least one aqueous solution. In some embodiments, the solution comprises, consists of, or consists essentially of at least one alcohol solvent. In some embodiments, the solution comprises, consists of, or consists essentially of at least one pH adjuster.

The solution may also be formulated or configured to remove at least one impurity from the layer of the polystyrene-b-polymethyl methacrylate block copolymer. In some embodiments, the solution removes the impurity present in the first region. In some embodiments, the solution removes the impurity present in the second region. In some embodiments, the solution removes the impurity present in the third region. In some embodiments, the solution removes a styrenic impurity. In some embodiments, the solution removes a methyl methacrylate impurity. In some embodiments, the solution removes at least one of the following: at least one additive, at least one byproduct, at least one residue (e.g., from the third region or intermixing region), or any combination thereof.

The solution may be formulating using any combination of the solution species disclosed herein. As used herein, the term “solution species” refers to any substance present in the solution. Non-limiting examples of solution species include solvents generally, such as, for example and without limitation, organic solvents, water, alcohol solvents, non-alcohol solvents, and the like; swelling controllers; pH adjusters; and the like. In some embodiments, the solvent refers to a solution species present in an amount sufficient to remove the PMMA (e.g., the alcohol solvent). In some embodiments, the swell controller refers to a solution species which is present in an amount sufficient to control (e.g., at least reduce) swelling of the PS. In some embodiments, the swelling controller is a solution species that is present in an amount that is less than the amount of the solvent. In some embodiments, the swelling controller is a solution species that improves the CD and/or LCDU. In some embodiments, the swelling controller comprises a C₅-C₁₀ alcohol solvent and their isomers. In some embodiments, the swelling controller is an alcohol solvent, and the solvent is an alcohol solvent, both of which are combined in the solvent system. In some embodiments, the non-alcohol solvent improves CD. In some embodiments, a particular solution species may act as a solvent when present in the solution at a first concentration, and may act as a swell controller when present in the solution at a second concentration, wherein the first concentration is different from the second concentration. In some embodiments, the pH adjuster refers to a solution species that is present in an amount sufficient to adjust solution pH. As one non-limiting example, an alcohol solvent may function as a solvent at a first concentration; and the same alcohol solvent may function as a swelling controller at a second concentration, wherein the second concentration is less than the first concentration.

In some embodiments, the solution comprises, consists of, or consists essentially of a first organic solvent and a second organic solvent, wherein the second organic solvent is different from the first organic solvent. In some embodiments, the solution comprises, consists of, or consists essentially of a first organic solvent, a second organic solvent, wherein the second organic solvent is different from the first organic solvent, and a pH adjuster. In some embodiments, the solution comprises, consists of, or consists essentially of an organic solvent and an alcohol solvent. In some embodiments, the solution comprises, consists of, or consists essentially of an alcohol solvent and a pH adjuster. In some embodiments, the solution comprises, consists of, or consists essentially of an organic solvent, an alcohol solvent, and a pH adjuster. In some embodiments, the solution comprises, consists of, or consists essentially of water and a water-miscible alcohol solvent. In some embodiments, the solution comprises, consists of, or consists essentially of at least one of at least one solvent, at least one pH adjuster, or any combination thereof. In some embodiments, the solution comprises, consists of, or consists essentially of at least one of at least one alcohol solvent, at least one non-alcohol solvent, at least one pH adjuster, or any combination thereof. In some embodiments, the solution comprises, consists of, or consists essentially of at least one of at least one solvent, at least one swell controller, at least one pH adjuster, or any combination thereof. In some embodiments, the solution comprises, consists of, or consists essentially of at least one of at least one organic solvent, at least one water-miscible organic solvent, at least one water, or any combination thereof.

In some embodiments, the solution comprises at least one of the following: at least one of acetone, acetic acid, diethylene glycol dibutyl ether, methyl ethyl ketone, methyl isobutyl ketone, cyclohexane, cyclohexanone, toluene, dichloromethane, tetrahydrofurfuryl alcohol, 2-phenoxyethanol, ethylene glycol butyl ether, 1-butanol, 2-ethoxyethyl acetate, n-butyl acetate, ethyl acetate, 1-heptanol, 1-butoxy-2-propanol, triethylamine, benzyl benzoate, bromobenzene, propylene glycol monobutyl ether, propylene glycol methyl ether (PGME), ethylene glycol monobutyl ether, ethylene glycol monoethyl ether acetate, ethanol, propanol, isopropanol, 1-butanol, 1-pentanol, 2-pentanol, 1-hexanol, 1-(2-hydroxyethyl)-2-pyrrolidone, 4-hydroxy-4-methyl-2-pentanone, hexylene glycol, triethylene glycol, or any combination thereof.

In some embodiments, the solution comprises at least one of the following: acetic acid, acetone, acetonitrile, benzene, 1-butanol, 2-butanol, 2-butanone, carbon tetrachloride, chlorobenzene, chloroform, cyclohexane, 1,2-dichloroethane, diethylene glycol, diethyl ether, diethylene glycol dimethyl ether, dimethyl formamide, dimethyl sulfoxide, 1,4-dioxane, ethanol, ethyl acetate, ethylene glycol, glycerin, methanol, ethanol, isopropanol, ethyl lactate, ethylene glycol, propylene glycol monomethyl ether, cyclohexanol, N-methyl-2-pyrrolidone, propyleneglycol monomethyl ether acetate, polyarylethers, hexamethyldisilazane, or any combination thereof.

In some embodiments, the solution comprises at least one of pentane, hexane, heptane, octane, nonane, decane, benzene, toluene, xylene, 2,2,4-trimethylpentane, cyclohexane, cyclohexane, ethylbenzene, ketones, acetone, methyl ethyl ketone, methyl isobutyl ketone, cyclohexanone, acetophenone, N-methyl-2-pyrrolidone, diethyl ether, dissopropyl ether, dibutyl ether, methyl tert butyl ether, 1,4-dioxane, tetrahydrofuran, esters, methyl acetate, ethyl acetate, isopropyl acetate, n-butyl acetate, glycol ethers, propylene glycol, methyl ether, ethylene glycol methyl ether, ethylene glycol ethyl ether, ethylene glycol monobutyl ether, methylene chloride, chloroform, carbon tetrachloride, 1,2-dichloroethane, trichloroethane, trichloroethylene, perchloroethylene, monochlorobenzene, dimethylformamide, dimethyl acetamide, acetic acid, aniline, nitrobenzene, pyridine, phenol, or any combination thereof.

In some embodiments, the organic solvent does not comprise an alcohol solvent, when the solution comprises an alcohol solvent. In some embodiments, the alcohol solvent comprises at least one of methanol, ethanol, n-propanol, isopropanol, n-butanol, iso-butanol, 2-butanol, 1-pentanol, 1-hexanol, heptanol, amyl alcohol, cyclohexanol, n-octanol, ethanediol, diethylene glycol, 1,2-propanediol, or any combination thereof. In some embodiments, the alcohol solvent comprises any one or more of the alcohols disclosed herein.

In some embodiments, the pH adjuster comprises at least one of the following: at least one of methanesulfonic acid, acetic acid, octanoic acid, formic acid, phosphoric acid, choline hydroxide, diethyl amine, methanol amine, N-(3-amino propyl) diethanolamine, 2-(butyl amino) ethanol, 2-(tert-butyl amino) ethanol, 2-(2-amino ethoxy) ethanol, 3-amino-1-propanol, tetrabutylammonium hydroxide (TBAH), tetramethylammonium hydroxide (TMAH), tetraethylammonium hydroxide (TEAH), tetrapropylammonium hydroxide (TPAH), (ETAMH), triethylamine (TEA), triethanolamine, ethanolamine (ETA), or any combination thereof.

In some embodiments, the solution comprises at least one of at least one solvent, at least one pH adjuster, or any combination thereof. In some embodiments, the at least one solvent comprises at least one of 1-butanol, propylene glycol methyl ether (PGME), 1-heptanol, or any combination thereof. In some embodiments, the at least one pH adjuster comprises at least one of 70% methane sulfonic acid (MSA), acetic acid, octanoic acid, triethanol amine, 2-(2-amino ethoxy) ethanol, 40% tetrabutylammonium hydroxide (TBAH), or any combination thereof.

In some embodiments, the solution comprises at least one of at least one alcohol solvent, at least one non-alcohol solvent, at least one pH adjuster, or any combination thereof. In some embodiments, the alcohol solvent comprises 1-butanol. In some embodiments, the at least one non-alcohol solvent comprises at least one of cyclohexanone, methyl isobutyl ketone (MIBK), butyl acetate, 1-heptanol, or any combination thereof. In some embodiments, the pH adjuster comprises 3-amino-1-propanol.

In some embodiments, the solution comprises at least one of at least one solvent, at least one swell controller, at least one pH adjuster, or any combination thereof. In some embodiments, the at least one solvent comprises at least one of 1-butanol, propylene glycol methyl ether (PGME), or any combination thereof. In some embodiments, the at least one swell controller comprises at least one of 1-pentanol, 2-pentanol, 1-heptanol, 2-heptanol, 3-heptanol, 1-hexanol, 2-hexanol, 3-hexanol, 2,4-dimethyl-3-pentanol, 1-octanol, methanol, ethanol, n-propanol, isopropanol, n-butanol, iso-butanol, 2-butanol, pentanol, amyl alcohol, cyclohexanol, n-octanol, ethanediol, diethylene glycol, 1,2-propanediol, or any combination thereof. In some embodiments, the pH adjuster comprises tetrabutylammonium hydroxide (TBAH). In some embodiments, the swell controller comprises a linear C₁-C₂₀ alcohol. In some embodiments, the swell controller comprises a branched C₂-C₂₀ alcohol.

In some embodiments, the solution comprises 5% to 90% by weight of the at least one solvent based on a total weight of the solution, or any range or subrange between 5% to 90%. In some embodiments, the solution comprises 5% to 85%, 5% to 80%, 5% to 75%, 5% to 70%, 5% to 65%, 5% to 60%, 5% to 55%, 5% to 50%, 5% to 45%, 5% to 40%, 5% to 35%, 5% to 30%, 5% to 25%, 5% to 20%, 5% to 15%, 5% to 10%, 10% to 90%, 15% to 90%, 20% to 90%, 30% to 90%, 35% to 90%, 40% to 90%, 45% to 90%, 50% to 90%, 55% to 90%, 60% to 90%, 65% to 90%, 70% to 90%, 75% to 90%, 80% to 90%, 85% to 90%, 45% to 65%, 45% to 60%, 45% to 55%, 45% to 50%, 50% to 65%, 55% to 65%, 60% to 65%, 15% to 30%, 20% to 30%, 25% to 30%, 15% to 25%, or 15% to 20% by weight of the at least one solvent based on a total weight of the solution.

In some embodiments, the solution comprises 0.1% to 20% by weight of the at least one pH adjuster based on the total weight of the solution, or any range or subrange between 0.1% to 20%. In some embodiments, the solution comprises 0.1% to 19%, 0.1% to 18%, 0.1% to 17%, 0.1% to 16%, 0.1% to 15%, 0.1% to 14%, 0.1% to 13%, 0.1% to 12%, 0.1% to 11%, 0.1% to 10%, 0.1% to 9%, 0.1% to 8%, 0.1% to 7%, 0.1% to 6%, 0.1% to 5%, 0.1% to 4%, 0.1% to 3%, 0.1% to 2%, 0.1% to 1%, 0.1% to 0.9%, 0.1% to 0.8%, 0.1% to 0.7%, 0.1% to 0.6%, 0.1% to 0.5%, 0.1% to 0.4%, 0.1% to 0.3%, 0.1% to 0.2%, 0.5% to 20%, 1% to 20%, 2% to 20%, 3% to 20%, 4% to 20%, 5% to 20%, 6% to 20%, 7% to 20%, 8% to 20%, 9% to 20%, 10% to 20%, 11% to 20%, 12% to 20%, 13% to 20%, 14% to 20%, 15% to 20%, 16% to 20%, 17% to 20%, 18% to 20%, or 19% to 20% by weight of the at least one pH adjuster based on the total weight of the solution.

In some embodiments, the solution comprises 50% to 99% by weight of the at least one alcohol solvent based on the total weight of the solution, or any range or subrange between 50% and 99%. In some embodiments, the solution comprises 50% to 95%, 50% to 90%, 50% to 85%, 50% to 80%, 50% to 75%, 50% to 70%, 50% to 65%, 50% to 60%, 50% to 55%, 55% to 99%, 60% to 99%, 65% to 99%, 70% to 99%, 75% to 99%, 80% to 99%, 85% to 99%, 90% to 99%, or 95% to 99% by weight of the at least one alcohol solvent based on the total weight of the solution.

In some embodiments, the solution comprises 1% to 50% by weight of the at least one non-alcohol solvent based on the total weight of the solution, or any range or subrange between 1% and 50%. In some embodiments, the solution comprises 1% to 45%, 1% to 40%, 1% to 35%, 1% to 30%, 1% to 25%, 1% to 20%, 1% to 15%, 1% to 10%, 1% to 5%, 5% to 50%, 10% to 50%, 15% to 50%, 20% to 50%, 25% to 50%, 30% to 50%, 35% to 50%, 40% to 50%, or 45% to 50% by weight of the at least one non-alcohol solvent based on the total weight of the solution.

In some embodiments, the solution comprises 1% to 25% by weight of the at least one swell controller based on the total weight of the solution, or any range or subrange between 1% to 25%. In some embodiments, the solution comprises 1% to 24%, 1% to 22%, 1% to 20%, 1% to 18%, 1% to 16%, 1% to 15%, 1% to 14%, 1% to 12%, 1% to 10%, 1% to 8%, 1% to 6%, 1% to 5%, 1% to 4%, 1% to 2%, 2% to 25%, 4% to 25%, 5% to 25%, 6% to 25%, 8% to 25%, 10% to 25%, 12% to 25%, 14% to 25%, 15% to 25%, 16% to 25%, 18% to 25%, 20% to 25%, 22% to 25%, or 24% to 25% by weight of the at least one swell controller based on the total weight of the solution.

In some embodiments, the solution comprises 5% to 90% by weight of the at least one organic solvent based on the total weight of the solution, or any range or subrange between 5% to 90%. In some embodiments, the solution comprises 5% to 85%, 5% to 80%, 5% to 75%, 5% to 70%, 5% to 65%, 5% to 60%, 5% to 55%, 5% to 50%, 5% to 45%, 5% to 40%, 5% to 35%, 5% to 30%, 5% to 25%, 5% to 20%, 5% to 15%, 5% to 10%, 10% to 90%, 15% to 90%, 20% to 90%, 30% to 90%, 35% to 90%, 40% to 90%, 45% to 90%, 50% to 90%, 55% to 90%, 60% to 90%, 65% to 90%, 70% to 90%, 75% to 90%, 80% to 90%, 85% to 90%, 45% to 65%, 45% to 60%, 45% to 55%, 45% to 50%, 50% to 65%, 55% to 65%, 60% to 65%, 15% to 30%, 20% to 30%, 25% to 30%, 15% to 25%, or 15% to 20% by weight of the at least one organic solvent based on a total weight of the solution.

In some embodiments, the solution comprises 5% to 90% by weight of the water based on the total weight of the solution, or any range or subrange between 5% to 90%. In some embodiments, the solution comprises 5% to 85%, 5% to 80%, 5% to 75%, 5% to 70%, 5% to 65%, 5% to 60%, 5% to 55%, 5% to 50%, 5% to 45%, 5% to 40%, 5% to 35%, 5% to 30%, 5% to 25%, 5% to 20%, 5% to 15%, 5% to 10%, 10% to 90%, 15% to 90%, 20% to 90%, 30% to 90%, 35% to 90%, 40% to 90%, 45% to 90%, 50% to 90%, 55% to 90%, 60% to 90%, 65% to 90%, 70% to 90%, 75% to 90%, 80% to 90%, 85% to 90%, 45% to 65%, 45% to 60%, 45% to 55%, 45% to 50%, 50% to 65%, 55% to 65%, 60% to 65%, 15% to 30%, 20% to 30%, 25% to 30%, 15% to 25%, 10% to 95%, or 15% to 20% by weight of the water based on a total weight of the solution.

In some embodiments, the solution has a pH in a range of 0 to 14, or any range or subrange therebetween. In some embodiments, the solution has a neutral pH (e.g., a pH of about 7). In some embodiments, the solution has a pH of 0 to 6, 1 to 6, 2 to 6, 3 to 6, 4 to 6, 5 to 6, 0 to 5, 0 to 4, 0 to 3, 0 to 2, 0 to 1, or any range or subrange therebetween. In some embodiments, the solution has a pH of 8 to 14, 8 to 13, 8 to 12, 8 to 11, 8 to 10, 8 to 9, 9 to 14, 10 to 14, 11 to 14, 12 to 14, 13 to 14, or any range or subrange therebetween.

In some embodiments, the contacting results in forming a porous layer. In some embodiments, the porous layer comprises a plurality of pores. In some embodiments, the porous layer comprises a plurality of nanopores. In some embodiments, the porous layer comprises a plurality of isopores. In some embodiments, the pores of the porous layer have an average pore diameter of 100 nm or less, 90 nm or less, 80 nm or less, 70 nm or less, 60 nm or less, 50 nm or less, 40 nm or less, 30 nm or less, 20 nm or less, 10 nm or less, or 5 nm or less. In some embodiments, the pores of the porous layer have an average pore diameter of 1 nm to 100 nm, or any range or subrange therebetween. For example, the pores of the porous layer may have an average pore diameter of 1 nm to 90 nm, 1 nm to 80 nm, 1 nm to 70 nm, 1 nm to 60 nm, 1 nm to 50 nm, 1 nm to 40 nm, 1 nm to 30 nm, 1 nm to 20 nm, 1 nm to 10 nm, 1 nm to 5 nm, 5 nm to 100 nm, 10 nm to 100 nm, 20 nm to 100 nm, 30 nm to 100 nm, 40 nm to 100 nm, 50 nm to 100 nm, 60 nm to 100 nm, 70 nm to 100 nm, 80 nm to 100 nm, or 90 nm to 100 nm. In some embodiments, the pores of the porous layer have an average pore diameter of 10 nm to 70 nm, 10 nm to 60 nm, 10 nm to 50 nm, 10 nm to 40 nm, 10 nm to 30 nm, 10 nm to 20 nm, 20 nm to 70 nm, 30 nm to 70 nm, 40 nm to 70 nm, 50 nm to 70 nm, 60 nm to 70 nm.

In some embodiments, the contacting results in forming a layer having a surface morphology. For example, in some embodiments, the contacting results in a layer having a patterned surface. The patterned surface may have at least one of lines, spaces, ridges, pillars, valleys, any combination thereof, and the like.

Some embodiments relate to a porous layer or a layer having a surface morphology. In some embodiments, the porous layer comprises any porous layer formed according to any of the methods disclosed herein. In some embodiments, the porous layer is useful as a mask for pattern transfer. In some embodiments, the layer has any of the surface morphologies disclosed herein.

Some embodiments relate to a method comprising obtaining a layer of a polystyrene-b-polymethyl methacrylate block copolymer, wherein the layer comprises a plurality of polymer domains, each of the plurality of polymer domains comprising: a first region comprising polystyrene chains; a second region comprising polymethyl methacrylate chains; contacting the layer with a solution to remove at least a portion of the polymethyl methacrylate chains from the second region, so as to form a porous layer or a layer having a surface morphology, wherein the solution removes a greater proportion of the polymethyl methacrylate chains than the polystyrene chains.

In some embodiments, the solution comprises an organic solvent.

In some embodiments, the solution comprises an aqueous solution.

In some embodiments, the solution comprises an alcohol solvent.

In some embodiments, the solution comprises a pH adjuster.

In some embodiments, the solution comprises: a first organic solvent, and a second organic solvent, wherein the second organic solvent is different from the first organic solvent.

In some embodiments, the solution comprises: a first organic solvent, a second organic solvent, wherein the second organic solvent is different from the first organic solvent, and a pH adjuster.

In some embodiments, the solution comprises: an organic solvent, and an alcohol solvent.

In some embodiments, the solution comprises: an alcohol solvent, and a pH adjuster.

In some embodiments, the solution comprises: an organic solvent, an alcohol solvent, and a pH adjuster.

In some embodiments, the solution comprises: water; and a water-miscible alcohol solvent.

In some embodiments, the solution comprises at least one of the following organic solvents: at least one of acetone, acetic acid, diethylene glycol dibutyl ether, methyl ethyl ketone, methyl isobutyl ketone, cyclohexane, cyclohexanone, toluene, dichloromethane, tetrahydrofurfuryl alcohol, 2-phenoxyethanol, ethylene glycol butyl ether, 1-butanol, 2-ethoxyethyl acetate, n-butyl acetate, ethyl acetate, 1-heptanol, 1-butoxy-2-propanol, triethylamine, benzyl benzoate, bromobenzene, propylene glycol monobutyl ether, propylene glycol methyl ether (PGME), ethylene glycol monobutyl ether, ethylene glycol monoethyl ether acetate, ethanol, propanol, isopropanol, 1-butanol, 1-pentanol, 1-hexanol, 1-(2-hydroxyethyl)-2-pyrrolidone, 4-hydroxy-4-methyl-2-pentanone, hexylene glycol, triethylene glycol, or any combination thereof.

In some embodiments, the solution comprises at least one of the following pH adjusters: at least one of methanesulfonic acid, acetic acid, octanoic acid, formic acid, phosphoric acid, choline hydroxide, diethyl amine, methanol amine, N-(3-amino propyl) diethanolamine, 2-(butyl amino) ethanol, 2-(tert-butyl amino) ethanol, 2-(2-amino ethoxy) ethanol, 3-amino-1-propanol, tetrabutylammonium hydroxide (TBAH), tetramethylammonium hydroxide (TMAH), tetraethylammonium hydroxide (TEAH), tetrapropylammonium hydroxide (TPAH), (ETAMH), triethylamine (TEA), triethanolamine, or any combination thereof.

In some embodiments, the solution removes a greater proportion of the polymethyl methacrylate chains present in the second region than the polystyrene chains present in the first region.

In some embodiments, each of the plurality of polymer domains further comprises: a third region between the first region and the second region, wherein the third region is an intermixed region, wherein the intermixed region comprises an unsegregated portion of polystyrene chains and polymethyl methacrylate chains.

In some embodiments, the solution removes at least a portion of the polymethyl methacrylate chains from the third region.

In some embodiments, the solution removes a greater proportion of the polymethyl methacrylate chains present in the third region than the polystyrene chains present in the third region.

In some embodiments, the solution removes a greater proportion of the polymethyl methacrylate chains present in the third region than the polystyrene chains present in the first region.

In some embodiments, the solution removes a greater proportion of the polymethyl methacrylate chains present in the second region than the polystyrene chains present in the third region.

In some embodiments, the porous layer comprises a plurality of nanopores.

In some embodiments, the porous layer comprises pores having an average pore diameter of 100 nm or less.

Some embodiments relate to a method comprising: obtaining a layer of a polystyrene-b-polymethyl methacrylate block copolymer, wherein the layer comprises a plurality of polymer domains, each of the plurality of polymer domains comprising: a first region comprising polystyrene chains; a second region comprising polymethyl methacrylate chains; exposing the layer to ultraviolet light, wherein the ultraviolet light cleaves at least a portion of the polymethyl methacrylate chains present in the second region; contacting the layer with a solution to remove at least a portion of the polymethyl methacrylate chains from the second region, so as to form a porous layer or a layer having a surface morphology, wherein the solution removes a greater proportion of the polymethyl methacrylate chains than the polystyrene chains.

In some embodiments, the solution comprises an organic solvent.

In some embodiments, the solution comprises an aqueous solution.

In some embodiments, the solution comprises an alcohol solvent.

In some embodiments, the solution comprises a swelling controller.

In some embodiments, the solution comprises a pH adjuster.

In some embodiments, the solution comprises: a first organic solvent, and a second organic solvent, wherein the second organic solvent is different from the first organic solvent.

In some embodiments, the solution comprises: a first organic solvent, a second organic solvent, wherein the second organic solvent is different from the first organic solvent, and a pH adjuster.

In some embodiments, the solution comprises: an organic solvent, and an alcohol solvent.

In some embodiments, the solution comprises: an alcohol solvent, and a pH adjuster.

In some embodiments, the solution comprises: an organic solvent, an alcohol solvent, and a pH adjuster.

In some embodiments, the solution comprises: water; and a water-miscible alcohol solvent.

In some embodiments, the solution comprises at least one of the following organic solvents: at least one of acetone, acetic acid, diethylene glycol dibutyl ether, methyl ethyl ketone, methyl isobutyl ketone, cyclohexane, cyclohexanone, toluene, dichloromethane, tetrahydrofurfuryl alcohol, 2-phenoxyethanol, ethylene glycol butyl ether, 1-butanol, 2-ethoxyethyl acetate, n-butyl acetate, ethyl acetate, 1-heptanol, 1-butoxy-2-propanol, triethylamine, benzyl benzoate, bromobenzene, propylene glycol monobutyl ether, ethylene glycol monobutyl ether, ethylene glycol monoethyl ether acetate, ethanol, propanol, isopropanol, 1-butanol, 1-pentanol, 1-hexanol, 1-(2-hydroxyethyl)-2-pyrrolidone, 4-hydroxy-4-methyl-2-pentanone, hexylene glycol, triethylene glycol, or any combination thereof.

In some embodiments, the solution comprises at least one of the following pH adjusters: at least one of methanesulfonic acid, acetic acid, formic acid, phosphoric acid, choline hydroxide, diethyl amine, methanol amine, N-(3-amino propyl) diethanolamine, 2-(butyl amino) ethanol, 2-(tert-butyl amino) ethanol, tetramethylammonium hydroxide (TMAH), tetraethylammonium hydroxide (TEAH), tetrapropylammonium hydroxide (TPAH), ethyltrimethylammonium hydroxide (ETAMH), triethylamine (TEA), triethanolamine, or any combination thereof.

In some embodiments, the solution removes a greater proportion of the polymethyl methacrylate chains present in the second region than the polystyrene chains present in the first region.

In some embodiments, each of the plurality of polymer domains further comprises: a third region between the first region and the second region, wherein the third region is an intermixed region, wherein the intermixed region comprises an unsegregated portion of polystyrene chains and polymethyl methacrylate chains.

In some embodiments, the solution removes at least a portion of the polymethyl methacrylate chains from the third region.

In some embodiments, the solution removes a greater proportion of the polymethyl methacrylate chains present in the third region than the polystyrene chains present in the third region.

In some embodiments, the solution removes a greater proportion of the polymethyl methacrylate chains present in the third region than the polystyrene chains present in the first region.

In some embodiments, the solution removes a greater proportion of the polymethyl methacrylate chains present in the second region than the polystyrene chains present in the third region.

In some embodiments, the porous layer comprises a plurality of nanopores.

In some embodiments, the porous layer comprises pores having an average pore diameter of 100 nm or less.

Some embodiments relate to a method comprising: obtaining a layer of a polystyrene-b-polymethyl methacrylate block copolymer, wherein the layer comprises a plurality of polymer domains, each of the plurality of polymer domains comprising: a first region comprising polystyrene chains; a second region comprising polymethyl methacrylate chains; a third region between the first region and the second region, wherein the third region comprises an unsegregated portion of polystyrene chains and polymethyl methacrylate chains; contacting the layer with a solution to remove at least a portion of the polymethyl methacrylate chains from the second region and the third region, so as to form a porous layer or a layer having a surface morphology, wherein the solution removes a greater proportion of the polymethyl methacrylate chains than the polystyrene chains.

In some embodiments, the solution comprises an organic solvent.

In some embodiments, the solution comprises an aqueous solution.

In some embodiments, the solution comprises an alcohol solvent.

In some embodiments, the solution comprises a pH adjuster.

In some embodiments, the solution comprises: a first organic solvent, and a second organic solvent, wherein the second organic solvent is different from the first organic solvent.

In some embodiments, the solution comprises: a first organic solvent, a second organic solvent, wherein the second organic solvent is different from the first organic solvent, and a pH adjuster.

In some embodiments, the solution comprises: an organic solvent, and an alcohol solvent.

In some embodiments, the solution comprises: an alcohol solvent, and a pH adjuster.

In some embodiments, the solution comprises: an organic solvent, an alcohol solvent, and a pH adjuster.

In some embodiments, the solution comprises: water; and a water-miscible alcohol solvent.

In some embodiments, the solution comprises at least one of the following organic solvents: at least one of acetone, acetic acid, diethylene glycol dibutyl ether, methyl ethyl ketone, methyl isobutyl ketone, cyclohexane, cyclohexanone, toluene, dichloromethane, tetrahydrofurfuryl alcohol, 2-phenoxyethanol, ethylene glycol butyl ether, 1-butanol, 2-ethoxyethyl acetate, n-butyl acetate, ethyl acetate, 1-heptanol, 1-butoxy-2-propanol, triethylamine, benzyl benzoate, bromobenzene, propylene glycol monobutyl ether, ethylene glycol monobutyl ether, ethylene glycol monoethyl ether acetate, ethanol, propanol, isopropanol, 1-butanol, 1-pentanol, 1-hexanol, 1-(2-hydroxyethyl)-2-pyrrolidone, 4-hydroxy-4-methyl-2-pentanone, hexylene glycol, triethylene glycol, or any combination thereof.

In some embodiments, the solution comprises at least one of the following pH adjusters: at least one of methanesulfonic acid, acetic acid, formic acid, phosphoric acid, choline hydroxide, diethyl amine, methanol amine, N-(3-amino propyl) diethanolamine, 2-(butyl amino) ethanol, 2-(tert-butyl amino) ethanol, tetramethylammonium hydroxide (TMAH), tetraethylammonium hydroxide (TEAH), tetrapropylammonium hydroxide (TPAH), ethyltrimethylammonium hydroxide (ETAMH), triethylamine (TEA), triethanolamine, or any combination thereof.

In some embodiments, the solution removes a greater proportion of the polymethyl methacrylate chains present in the second region than the polystyrene chains present in the first region.

In some embodiments, the solution removes at least a portion of the polymethyl methacrylate chains from the third region.

In some embodiments, the solution removes a greater proportion of the polymethyl methacrylate chains present in the third region than the polystyrene chains present in the third region.

In some embodiments, the solution removes a greater proportion of the polymethyl methacrylate chains present in the third region than the polystyrene chains present in the first region.

In some embodiments, the solution removes a greater proportion of the polymethyl methacrylate chains present in the second region than the polystyrene chains present in the third region.

In some embodiments, the porous layer comprises a plurality of nanopores.

In some embodiments, the porous layer comprises pores having an average pore diameter of 100 nm or less.

### EXAMPLES

### General Methods

In-beaker soaking method: A 50 ml testing solution prepared by weight percentage was prepared in a 100 ml glass beaker. Gently stirring at 120 rpm at room temperature, a piece of wafer coupon pinched by a PP tweezer got fully immersed in the solution then soaked for 10 to 180 sec depending on test conditions. Subsequently the coupon was lifted and directly put into another beaker with flowing DIW for 1 min rinsing followed by N2 blow dry. Especially for etch rate study and for swell inhibition study, film thickness measurement was carried out before and after the soaking process by using a coupon piece of a homo-PS or homo-PMMA coated film sample.

Spin-on puddle method: A piece of wafer coupon was placed on a flat stage of a spin coater (MIKASA MS-B300), fixed sucking down by a vacuum pump. Onto the surface of the coupon was dropped a 0.5 ml testing solution which immediately covered the surface fully. After keeping it still for a required amount of process time for puddle, the coupon got spin-dried at 1500 rpm to get the surface dry anduniform.

Functional test with patterned wafer coupons: A 1×1 cm2 size of wafer coupon was processed either by in-beaker soaking or by spin-on for a required amount of process time. For pattern observation, Scanning Electron Microscopy (Hitachi SU-8220) was conducted with Pt coating. Image data was worked for metrology to analyze LCDU and Twisting by using measurement algorithms and statistical processing applied for CD-SEM.

### Example 1

### Mixture of Solvent and pH Adjustor

Several formulations (Samples A-F) were prepared with varying pH, and the PMMA removal performance of each formulation was evaluated. A mixture of 1-butanol, propylene glycol methyl ether (PGME), and 1-heptanol were combined with a pH adjuster and blended by stirring at room temperature. Theformulations for Samples A-F and the corresponding PMMA removal performance for each of the formulations are summarized in Table 1 and Table 2 below.

TABLE 1

| | | | | pH Adjustor (wt %) | | | | | | |
|---|---|---|---|---|---|---|---|---|---|---|
| | | | | | | | | 2-(2- | | |
| | | | Swelling | | | | | Amino | | |
| Sample | Solvent (wt %) | | controller | 70% | Acetic | Octanoic | Triethanol | Ethoxy) | 40% | |
| No. | 1-Butanol | PGME | 1-Heptanol | MSA | Acid | Acid | Amine | Ethanol | TBAH | pH |
| A | 62.3 | 26.7 | 10 | 1 | | | | | | <0 |
| B | 57.4 | 24.6 | 10 | | 8 | | | | | 3 |
| C | 57.4 | 24.6 | 10 | | | 8 | | | | 3 |
| D | 57.4 | 24.6 | 10 | | | | 8 | | | 9 |
| E | 57.4 | 24.6 | 10 | | | | | 8 | | 11 |
| F | 62.5 | 26.8 | 10 | | | | | | 0.7 | 15 |

The pKa values for each pH adjuster included 70% MSA (−1.9 pKa), acetic acid (4.6 pKa), octanoic acid (4.9 pKa), triethanol amine (7.9 pKa), 2-(2-amino ethoxy) ethanol (9.6 pKa), 40% TBAH (14 pKa).

TABLE 2

PMMA Removal Performance

| Sample | Hole | LCDU Reduction |
|---|---|---|
| No. | CD (nm) | from IPA(%) |
| A | 20.9 | 16.9 |
| B | 21.3 | 8.4 |
| C | 20.0 | 20.6 |
| D | 20.9 | −1.9 |
| E | 21.8 | 0.8 |
| F | 17.9 | 4.5 |

As shown in Tables 1 and 2, alkaline systems unexpectedly performed better than acidic systems.

### Example 2

### Mixture of Alcohol Solvent, Non-Alcohol Solvent, and pH Adjuster

Several formulations (Samples G-I) were prepared, and the PMMA removal performance of each formulation was evaluated. An alcohol solvent and a non-alcohol solvent were combined with a pH adjuster and blended by stirring at room temperature. The formulations for Samples G-I and the corresponding PMMA removal performance for each of the formulations are summarized in Table 3 and Table 4 below.

TABLE 3

| | Solvents | | | | | |
|---|---|---|---|---|---|---|
| | Alcohol | | | | | pHadjustor |
| | solvent | Non-alcohol solvent (wt %) | | | Swelling | (wt %) |
| Sample | (wt %) | | | Butyl | controller | 3-Amino-1- |
| No. | 1-Butanol | Cyclohexanone | MIBK | acetate | 1-Heptanol | propanol |
| G | 73.8 | 8.2 | | | 10 | 8 |
| H | 73.8 | | 8.2 | | 10 | 8 |
| I | 73.8 | | | 8.2 | 10 | 8 |

TABLE 4

| | PMMA removal performance | | |
|---|---|---|---|
| Sample | Hole | LCDU reduction | Twisting |
| No. | CD (nm) | from IPA (%) | (nm) |
| G | 16.5 | 16.7 | 1.3 |
| H | 16.3 | −14.2 | 1.4 |
| I | 16.0 | 33.6 | 1.7 |

### Example 3

### Mixture of Solvent, Swell Controller, and pH Adjuster

Several formulations (Samples J-Q) were prepared, and the PMMA removal performance of each formulation was evaluated. A solvent and a swell controller were combined with a pH adjuster and blended by stirring at room temperature. The formulations for Samples J-Q and the corresponding PMMA removal performance for each of the formulations are summarized in Table 5 and Table 6 below.

TABLE 5

| | | | Swell controller (wt %) | | | | | | | | pH |
|---|---|---|---|---|---|---|---|---|---|---|---|
| | | | | | | | | | 2,4- | | adjustor |
| | Solvent (wt %) | | | | | | | | Dimethyl- | | (wt %) |
| Sample | 1- | | 1- | 2- | 3- | 1- | 2- | 3- | 3- | 1- | 40% |
| No. | Butanol | PGME | Heptanol | Heptanol | Heptanol | Hexanol | Hexanol | Hexanol | pentanol | Octanol | TBAH |
| J | 62.5 | 26.8 | 10 | | | | | | | | 0.7 |
| K | 62.5 | 26.8 | | 10 | | | | | | | 0.7 |
| L | 62.5 | 26.8 | | | 10 | | | | | | 0.7 |
| M | 62.5 | 26.8 | | | | 10 | | | | | 0.7 |
| N | 62.5 | 26.8 | | | | | 10 | | | | 0.7 |
| O | 62.5 | 26.8 | | | | | | 10 | | | 0.7 |
| P | 62.5 | 26.8 | | | | | | | 10 | | 0.7 |
| Q | 62.5 | 26.8 | | | | | | | | 10 | 0.7 |

TABLE 6

| | PMMA removal performance | | |
|---|---|---|---|
| Sample | Hole | LCDU reduction | Twisting |
| No. | CD (nm) | from IPA (%) | (nm) |
| J | 17.9 | 4.5 | 1.3 |
| K | 17.2 | 13.6 | 1.6 |
| L | 16.6 | 20.1 | 1.4 |
| M | 17.3 | −3.94 | 1.4 |
| N | 16.4 | 65.5 | 1.5 |
| O | 14.9 | 101.4 | 1.7 |
| P | 16.6 | 0.63 | 1.2 |
| Q | 17.1 | 7.8 | 1.4 |

### Example 4

### Mixture of Water and Organic Solvent

Several formulations (Samples R-U) were prepared, and the PMMA removal performance of each formulation was evaluated. A water and an organic solvent were combined and blended by stirring at room temperature. The formulations for Samples R-U and the corresponding PMMA removal performance for each of the formulations are summarized in Table 7 below.

| | |
|---|---|
| Solvent (wt %) | PMMA removal performance |

| Sample | Acetic | | Hole CD | LCDU reduction |
|---|---|---|---|---|
| No. | acid | DIW | (nm) | from IPA (%) |
| R | 80 | 20 | 14.9 | 28.6 |
| S | 65 | 35 | 14.2 | 16.2 |
| T | 50 | 50 | 13.2 | 72.9 |
| U | 35 | 65 | 12.3 | 46.4 |

### Aspects

Various Aspects are described below. It is to be understood that any one or more of the features recited in the following Aspect(s) can be combined with any one or more other Aspect(s).

Aspect 1. A method comprising:
obtaining a layer of a polystyrene-b-polymethyl methacrylate block copolymer,
   wherein the layer comprises a plurality of polymer domains, each of the plurality of polymer domains comprising:
      a first region comprising polystyrene chains;
      a second region comprising polymethyl methacrylate chains;
contacting the layer with a solution to remove at least a portion of the polymethyl methacrylate chains from the second region,
   wherein the solution removes a greater proportion of the polymethyl methacrylate chains than the polystyrene chains.

Aspect 2. The method according to Aspect 1, wherein the solution comprises: 5% to 90% by weight of at least one solvent based on a total weight of the solution; and
0.1% to 20% by weight of at least one pH adjuster based on the total weight of the solution.

Aspect 3. The method according to Aspect 2, wherein the solution has a pH of less than 7.

Aspect 4. The method according to any one of Aspects 1-3, wherein the solution comprises:
50% to 99% by weight of at least one alcohol solvent based on a total weight of the solution;
1% to 50% by weight of at least one non-alcohol solvent based on the total weight of the solution; and
0.1% to 20% by weight of at least one pH adjuster based on the total weight of the solution.

Aspect 5. The method according to any one of Aspects 1-4, wherein the solution comprises:
5% to 90% by weight of at least one first alcohol solvent based on a total weight of the solution;
1% to 25% by weight of at least one swell controller based on the total weight of the solution, wherein the at least one swell controller is a second alcohol solvent that is different from the at least one first alcohol solvent; and
0.1% to 20% by weight of at least one pH adjuster based on the total weight of the solution.

Aspect 6. The method according to any one of Aspects 1-5, wherein the solution comprises:
5% to 90% by weight of at least one organic solvent based on a total weight of the solution; and
10% to 95% by weight of water based on the total weight of the solution.

Aspect 7. The method according to any one of Aspects 1-6, wherein the solution removes a greater proportion of the polymethyl methacrylate chains present in the second region than the polystyrene chains present in the first region.

Aspect 8. A method comprising:
obtaining a layer of a polystyrene-b-polymethyl methacrylate block copolymer,
   wherein the layer comprises a plurality of polymer domains, each of the plurality of polymer domains comprising:
      a first region comprising polystyrene chains;
      a second region comprising polymethyl methacrylate chains;
exposing the layer to ultraviolet light,
   wherein the ultraviolet light cleaves at least a portion of the polymethyl methacrylate chains present in the second region;
contacting the layer with a solution to remove at least a portion of the polymethyl methacrylate chains from the second region, so as to form a porous layer or a layer having a surface morphology,
   wherein the solution removes a greater proportion of the polymethyl methacrylate chains than the polystyrene chains.

Aspect 9. The method according to Aspect 8, wherein the solution comprises:
5% to 90% by weight of at least one solvent based on a total weight of the solution; and
0.1% to 20% by weight of at least one pH adjuster based on the total weight of the solution.

Aspect 10. The method according to Aspect 9, wherein the solution has a pH of less than 7.

Aspect 11. The method according to any one of Aspects 8-10, wherein the solution comprises:
50% to 99% by weight of at least one alcohol solvent based on a total weight of the solution;
1% to 50% by weight of at least one non-alcohol solvent based on the total weight of the solution; and
0.1% to 20% by weight of at least one pH adjuster based on the total weight of the solution.

Aspect 12. The method according to any one of Aspects 8-11, wherein the solution comprises:
5% to 90% by weight of at least one solvent based on a total weight of the solution;
1% to 25% by weight of at least one swell controller based on the total weight of the solution; and
0.1% to 20% by weight of at least one pH adjuster based on the total weight of the solution.

Aspect 13. The method according to any one of Aspects 8-12, wherein the solution comprises:
5% to 90% by weight of at least one organic solvent based on a total weight of the solution; and
10% to 95% by weight of water based on the total weight of the solution.

Aspect 14. The method according to any one of Aspects 8-13, wherein the solution removes a greater proportion of the polymethyl methacrylate chains present in the second region than the polystyrene chains present in the first region.

Aspect 15. A method comprising:
obtaining a layer of a polystyrene-b-polymethyl methacrylate block copolymer,
   wherein the layer comprises a plurality of polymer domains, each of the plurality of polymer domains comprising:
      a first region comprising polystyrene chains;
      a second region comprising polymethyl methacrylate chains;
      a third region between the first region and the second region,
         wherein the third region comprises an unsegregated portion of polystyrene chains and polymethyl methacrylate chains;
contacting the layer with a solution to remove at least a portion of the polymethyl methacrylate chains from the second region and the third region, so as to form a porous layer or a layer having a surface morphology,
   wherein the solution removes a greater proportion of the polymethyl methacrylate chains than the polystyrene chains.

Aspect 16. The method according to Aspect 15, wherein the solution comprises:
5% to 90% by weight of at least one solvent based on a total weight of the solution; and
0.1% to 20% by weight of at least one pH adjuster based on the total weight of the solution.

Aspect 17. The method according to Aspect 16, wherein the solution has a pH of less than 7.

Aspect 18. The method according to any one of Aspects 15-17, wherein the solution comprises:
50% to 99% by weight of at least one alcohol solvent based on a total weight of the solution;
1% to 50% by weight of at least one non-alcohol solvent based on the total weight of the solution; and
0.1% to 20% by weight of at least one pH adjuster based on the total weight of the solution.

Aspect 19. The method according to any one of Aspects 15-18, wherein the solution comprises:
5% to 90% by weight of at least one solvent based on a total weight of the solution;
1% to 25% by weight of at least one swell controller based on the total weight of the solution; and
0.1% to 20% by weight of at least one pH adjuster based on the total weight of the solution.

Aspect 20. The method according to any one of Aspects 15-19, wherein the solution comprises:
5% to 90% by weight of at least one organic solvent based on a total weight of the solution; and
10% to 95% by weight of water based on the total weight of the solution.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A method comprising:
obtaining a layer of a polystyrene-b-polymethyl methacrylate block copolymer,
wherein the layer comprises a plurality of polymer domains, each of the plurality of polymer domains comprising:
a first region comprising polystyrene chains;
a second region comprising polymethyl methacrylate chains;
contacting the layer with a solution to remove at least a portion of the polymethyl methacrylate chains from the second region,
wherein the solution removes a greater proportion of the polymethyl methacrylate chains than the polystyrene chains.

2. The method of claim 1, wherein the solution comprises:
5% to 90% by weight of at least one solvent based on a total weight of the solution; and
0.1% to 20% by weight of at least one pH adjuster based on the total weight of the solution.

3. The method of claim 2, wherein the solution has a pH of less than 7.

4. The method of claim 1, wherein the solution comprises:
50% to 99% by weight of at least one alcohol solvent based on a total weight of the solution;
1% to 50% by weight of at least one non-alcohol solvent based on the total weight of the solution; and
0.1% to 20% by weight of at least one pH adjuster based on the total weight of the solution.

5. The method of claim 1, wherein the solution comprises:
5% to 90% by weight of at least one first alcohol solvent based on a total weight of the solution;
1% to 25% by weight of at least one swell controller based on the total weight of the solution, wherein the at least one swell controller is a second alcohol solvent that is different from the at least one first alcohol solvent; and
0.1% to 20% by weight of at least one pH adjuster based on the total weight of the solution.

6. The method of claim 1, wherein the solution comprises:
5% to 90% by weight of at least one organic solvent based on a total weight of the solution; and
10% to 95% by weight of water based on the total weight of the solution.

7. The method of claim 1, wherein the solution removes a greater proportion of the polymethyl methacrylate chains present in the second region than the polystyrene chains present in the first region.

8. A method comprising:
obtaining a layer of a polystyrene-b-polymethyl methacrylate block copolymer,
wherein the layer comprises a plurality of polymer domains, each of the plurality of polymer domains comprising:
a first region comprising polystyrene chains;
a second region comprising polymethyl methacrylate chains; exposing the layer to ultraviolet light,
wherein the ultraviolet light cleaves at least a portion of the polymethyl methacrylate chains present in the second region;
contacting the layer with a solution to remove at least a portion of the polymethyl methacrylate chains from the second region, so as to form a porous layer or a layer having a surface morphology,
wherein the solution removes a greater proportion of the polymethyl methacrylate chains than the polystyrene chains.

9. The method of claim 8, wherein the solution comprises:
5% to 90% by weight of at least one solvent based on a total weight of the solution; and
0.1% to 20% by weight of at least one pH adjuster based on the total weight of the solution.

10. The method of claim 9, wherein the solution has a pH of less than 7.

11. The method of claim 8, wherein the solution comprises:
50% to 99% by weight of at least one alcohol solvent based on a total weight of the solution;
1% to 50% by weight of at least one non-alcohol solvent based on the total weight of the solution; and
0.1% to 20% by weight of at least one pH adjuster based on the total weight of the solution.

12. The method of claim 8, wherein the solution comprises:
5% to 90% by weight of at least one solvent based on a total weight of the solution;
1% to 25% by weight of at least one swell controller based on the total weight of the solution; and
0.1% to 20% by weight of at least one pH adjuster based on the total weight of the solution.

13. The method of claim 8, wherein the solution comprises:
5% to 90% by weight of at least one organic solvent based on a total weight of the solution; and
10% to 95% by weight of water based on the total weight of the solution.

14. The method of claim 8, wherein the solution removes a greater proportion of the polymethyl methacrylate chains present in the second region than the polystyrene chains present in the first region.

15. A method comprising:
obtaining a layer of a polystyrene-b-polymethyl methacrylate block copolymer,
wherein the layer comprises a plurality of polymer domains, each of the plurality of polymer domains comprising:
a first region comprising polystyrene chains;
a second region comprising polymethyl methacrylate chains;
a third region between the first region and the second region,
wherein the third region comprises an unsegregated portion of polystyrene chains and polymethyl methacrylate chains;
contacting the layer with a solution to remove at least a portion of the polymethyl methacrylate chains from the second region and the third region, so as to form a porous layer or a layer having a surface morphology,
wherein the solution removes a greater proportion of the polymethyl methacrylate chains than the polystyrene chains.

16. The method of claim 15, wherein the solution comprises:
5% to 90% by weight of at least one solvent based on a total weight of the solution; and
0.1% to 20% by weight of at least one pH adjuster based on the total weight of the solution.

17. The method of claim 16, wherein the solution has a pH of less than 7.

18. The method of claim 15, wherein the solution comprises:
50% to 99% by weight of at least one alcohol solvent based on a total weight of the solution;
1% to 50% by weight of at least one non-alcohol solvent based on the total weight of the solution; and
0.1% to 20% by weight of at least one pH adjuster based on the total weight of the solution.

19. The method of claim 15, wherein the solution comprises:
5% to 90% by weight of at least one solvent based on a total weight of the solution;
1% to 25% by weight of at least one swell controller based on the total weight of the solution; and
0.1% to 20% by weight of at least one pH adjuster based on the total weight of the solution.

20. The method of claim 15, wherein the solution comprises:
5% to 90% by weight of at least one organic solvent based on a total weight of the solution; and
10% to 95% by weight of water based on the total weight of the solution.
